(19) United States
(12) Patent Application Publication
(10) Pub. No.: US 2006/0285305 A1
(43) Pub. Date: Dec. 21, 2006

(54) Portable storage device

(75) Inventor: Naohisa Okumura, Yokohama-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/452,323

(22) Filed: Jun. 14, 2006

(30) Foreign Application Priority Data
Jun. 15, 2005 (JP) 2005-175025
Apr. 24, 2006 (JP) 2006-119243

(51) Int. Cl. H05K 5/00

(52) U.S. Cl. 361/752; 361/756; 361/757

(57) ABSTRACT

A portable storage device comprises a rectangular cover case having an opening formed on a front side surface; a circuit board which is supported in the cover case in a state of being inserted in the cover case from the opening, and which is provided with a connector terminal section in a front part; and a semiconductor storage device which is mounted on at least one of an upper surface side and a lower surface side of the circuit board and is connected with the connector terminal section, and which stores predetermined data, wherein the cover case has supporting sections which are formed in both right and left side walls of the cover case and which support the circuit board from right and left by elastic force in a state where the circuit board is inserted in the cover case.

### CROSS-REFERENCE TO RELATED APPLICATIONS

This application is based upon and claims the benefit of priority from the prior Japanese Patent Applications No. 2005-175025, filed on Jun. 15, 2005 and No. 2006-119243, filed on Apr. 24, 2006, the entire contents of which are incorporated herein by reference.

### BACKGROUND OF THE INVENTION

1. Field of the Invention

The present invention relates to a portable storage device provided with a cover case for protecting a circuit board which is mounted with a semiconductor storage device used by connecting with an external device.

2. Background Art

A cover case for the conventional portable storage device is used to protect electronic components and the like mounted on the circuit board, and therefore one superior is safety and has been used. One of conventional portable storage devices includes those a substrate connected to a USB connector head, a lower cover for protection from the lower surface side of the substrate, an upper cover for protection from the upper surface side of the substrate, and a case cover for containing the USB connector head, and the substrate is sandwiched by the upper cover and the lower cover, and the covers are fixed by bolts. (For example, refer to Japanese Utility Model Publication No. 3086524).

However, in the above described background art, since at least two or more components in total are required on the upper side and on the lower side of the substrate, as described above, the method for attaching the protection case (upper cover, lower cover) to the substrate is made complicated. As a result, there arise problems that assembly time of the portable storage device can not be shortened, and that manufacturing costs of the portable storage device can not be reduced.

### SUMMARY OF THE INVENTION

According one aspect of the present invention, there is provided: a portable storage device comprising a rectangular cover case having an opening formed on a front side surface; a circuit board which is supported in the cover case in a state of being inserted in the cover case from the opening, and which is provided with a connector terminal section in a front part; and a semiconductor storage device which is mounted on at least one of an upper surface side and a lower surface side of the circuit board and is connected with the connector terminal section, and which stores predetermined data, wherein the cover case has supporting sections which are formed in both right and left side walls of the cover case and which support the circuit board from right and left by elastic force in a state where the circuit board is inserted in the cover case.

### BRIEF DESCRIPTION OF THE DRAWINGS

FIG. 1 is a schematic diagram showing a main part construction of a circuit board of a portable storage device according to a First Embodiment of the present invention;

FIG. 2 is a schematic diagram showing a main part construction of a cover case of the portable storage device according to the First Embodiment of the present invention;

FIG. 3 is a schematic diagram showing a main part construction of the portable storage device according to the First Embodiment of the present invention;

FIG. 4 is a schematic diagram showing a main part construction of the portable storage device according to a Second Embodiment of the present invention;

FIG. 5 is a schematic diagram showing a main part construction of a cover case of a portable storage device according to a Third Embodiment of the present invention;

FIG. 6 is also a schematic diagram showing a main part construction of a portable storage device according to the Third Embodiment of the present invention;

FIG. 7 is a schematic diagram showing a main part construction of a cover case of a portable storage device according to a Fourth Embodiment of the present invention;

FIG. 8 is also a schematic diagram showing a main part construction of the portable storage device according to the Fourth Embodiment of the present invention;

FIG. 9 is a schematic diagram showing a main part construction of a portable storage device according to a Fifth Embodiment of the present invention;

FIG. 10 is a sectional view showing a main part construction of a portable storage device according to a Sixth Embodiment of the present invention;

FIG. 11 is a sectional view showing a main part construction of a portable storage device according to a Sixth Embodiment of the present invention; and

FIG. 12 is a schematic diagram showing a main part construction of a portable storage device according to a Seventh Embodiment of the present invention.

### DETAILED DESCRIPTION

In the following, embodiments to which the present invention is applied will be described with reference to the accompanying drawings. In the embodiments which will be described below, there are described specific examples where the present invention is applied to a USB memory unit as a portable storage device.

### First Embodiment

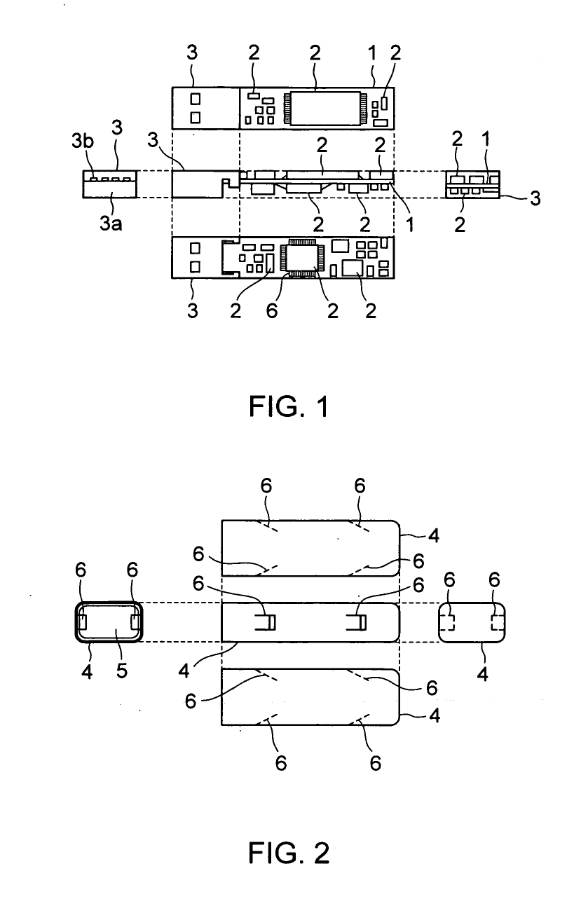

FIG. 1 is a schematic diagram showing a main part construction of a circuit board of a portable storage device according to a First Embodiment of the present invention.

As shown in FIG. 1, electronic components 2 are mounted on the upper surface side and the lower surface side of a rectangular circuit board 1 constituted by a substrate made of silicon and the like. The electronic components 2 include a semiconductor storage device for storing predetermined data and the like. It is to be noted that the electronic components 2 may be mounted on the circuit board 1 in a sealed state, or may be provided on the circuit board 1 and thereafter molded on the board.

A connector terminal section 3 as a USB terminal is provided in the front of the circuit board 1. The connector terminal section 3 has a substrate 3a and a metal terminal 3b which is formed on the substrate 3a and which is connected with the semiconductor storage device. By connecting the connector terminal section 3 to a terminal of an external device (not shown), the semiconductor storage device and the external device are adapted to perform transmission and reception of predetermined data them.

In addition, the circuit board 1 has a width almost equal to that of the connector terminal 3.

FIG. 2 is a schematic diagram showing a main part construction of a cover case of the portable storage device according to the First Embodiment of the present invention.

As shown in FIG. 2, the cover case 4 has a rectangular shape, and an opening 5 is formed in the front side of the cover case. The opening 5 has dimension larger than, for example, the size (4.5 mm in height, and 12 mm in width) of the connector terminal section 3 so that the circuit board 1 having the connector terminal section 3 can be inserted into the opening 5 at the time of assembling the portable storage device. Furthermore, the cover case 4 is constituted by a member made of, for example, plastic, metal and the like, and is formed by integrated molding.

As shown in FIG. 2, the cover case 4 has supporting sections 6 formed in both right and left side walls. The supporting sections 6 are formed in such a manner that U-shaped cuts are formed in both right and left side walls of the cover case 4 so as to be open at the rear side, and that each of the portions of the side walls in which the U-shaped cuts are formed is folded down to project inside the cover case 4. The supporting sections 6 are arranged to support the circuit board 1 from the left and right by the elastic force in a state where the circuit board 1 is inserted. That is, the cover case 4 is brought into contact with the side wall of the circuit board 1 at the end of the cut as the supporting section 6, so as to support the circuit board 1.

It is to be noted that the circuit board 1 may also be supported in such a manner that U-shaped cuts are formed in both right and left side walls of the cover case 4, and that when the circuit board 1 mounted with electronic components 2 is arranged at a predetermined position in the cover case 4, the supporting sections 6 are folded down inwardly and brought into contact with the circuit board 1 so as to make a pressure applied to the circuit board 1.

Furthermore, the end of the supporting section 6 preferably has, for example, a width set to be greater than about 0.3 mm in thickness of the circuit board 1, so as to be able to stably support the end of the circuit board 1.

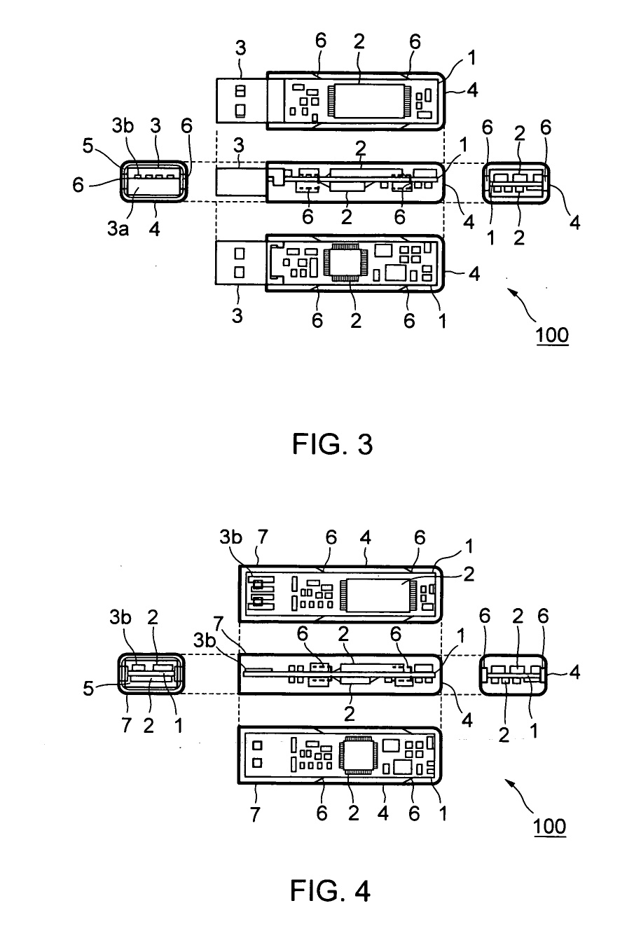

Here, FIG. 3 is a schematic diagram showing a main part construction of the portable storage device according to the First Embodiment of the present invention.

The portable storage device 100 is assembled in such a manner that the circuit board 1 mounted with electronic components 2 including a semiconductor storage device, is inserted to a predetermined position in the opening 5 of the cover case 4 from the rear side of the circuit board 1, so as to make both side surfaces of the circuit board 1 face the supporting sections 6. Thereby, as shown in FIG. 3, the circuit board 1 is supported in the cover case 4 in the state where the connector terminal section 3 is exposed, and the portable storage device 100 is completed.

In this way, the portable storage device 100 can be easily assembled without requiring other parts such as bolts.

It is to be noted that, for example, the circuit board 1 may be arranged to be stopped at the position where the circuit board 1 comes in contact with the rear side wall of the cover case 4, or a stopper (not shown) may be provided in the cover case 4 so as to make the inserted circuit board 1 supported at a predetermined position.

Furthermore, a recess may be respectively formed in a predetermined position of both right and left side surfaces of the circuit board 1, so as to be engaged with the supporting section 6, as a result of which the inserted circuit board 1 is supported at a predetermined position in the cover case 4.

As described above, since the portable storage device according to the present embodiment is provided with the cover case which is formed by integrated molding and which has the supporting sections for supporting the circuit board from the left and right by the elastic force in the state where the circuit board is inserted, it is possible to reduce the number of parts of the cover case, and to facilitate the assembly of the portable storage device, and as a result, assembly time and manufacturing costs of the portable storage device can be reduced.

### Second Embodiment

In the First Embodiment, a construction in which the connector terminal section provided in the circuit board includes the outer frame of the USB terminal, is described, but in the present embodiment, a construction in which an extended cover case is also used for the portion corresponding to the outer frame of the USB terminal, is described.

FIG. 4 is a schematic diagram showing a main part construction of the portable storage device according to a Second Embodiment of the present invention. It is to be noted that in the figure, the same reference numerals as those in the First Embodiment denote the same parts as those in the First Embodiment.

As shown in FIG. 4, a metal terminal 3b is directly provided as a connector terminal section on the upper surface of a circuit board 1. Furthermore, as the portion corresponding to the outer frame of the USB terminal, an extension 7 in a cover case 4 is formed extendedly so as to protect the metal terminal 3b. It is to be noted that other construction is the same as that of the First Embodiment.

As described above, since the portable storage device according to the present embodiment is provided with the cover case that is formed by integrated molding and that has the supporting sections for supporting the circuit board from the right and left by the elastic force in the state where the circuit board is inserted, it is possible to reduce the number of components of the cover case, and to further reduce the number of components of the circuit board, as a result of which assembly time and manufacturing costs of the portable storage device can be reduced.

### Third Embodiment

In the First and Second Embodiments, a construction in which both right and left side surfaces of the circuit board is supported by the ends of the supporting sections, is described, but in the present embodiment, another construction of the supporting section for supporting the circuit board is described.

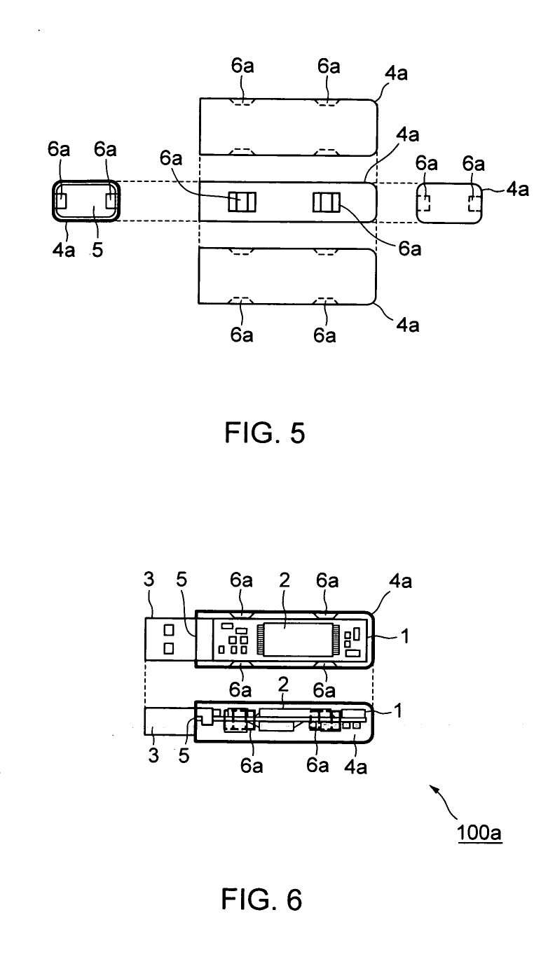

FIG. 5 is a schematic diagram showing a main part construction of a cover case of a portable storage device according to a Third Embodiment of the present invention. FIG. 6 is also a schematic diagram showing a main part construction of a portable storage device according to the Third Embodiment of the present invention. It is to be noted that in the figure, the same reference numerals as those in the First Embodiment denote the same components as those in the First Embodiment.

As shown in FIG. 5, supporting sections 6a are formed in such a manner that two cuts are provided so as to be in parallel with each other at respective positions in both right and left side walls of a cover case 4a, and that each portion of the side wall which is sandwiched between the two cuts are press-formed so as to project inside the cover case 4a. Therefore, a material having ductility, such as metal, is selected as the material of the cover case 4a.

The portable storage device 100a is assembled, similarly to the First Embodiment, in such a manner that the circuit board 1 mounted with electronic components 2 including a semiconductor storage device, is inserted to a predetermined position in the opening 5 of the cover case 4a from the rear side of the circuit board 1, so as to make both side surfaces of the circuit board 1 face the supporting sections 6a.

Thereby, as shown in FIG. 6, the circuit board 1 is supported in the cover case 4a in the state where the connector terminal section 3 is exposed, and the portable storage device 100a is completed.

Similarly to the First Embodiment, the portable storage device 100a can be easily assembled without requiring components such as other bolts.

It is to be noted that the circuit board 1 may also be supported in such a manner that two cuts are provided so as to be in parallel with each other at respective positions in both right and left side walls of the cover case 4a, that when the circuit board 1 mounted with electronic components 2 is arranged at a predetermined position in the cover case 4a, each portion of the side wall in which the two cuts are formed is subjected to press-shaping so as to be formed into the supporting section 6a, and that the circuit board 1 is brought into contact with the supporting section so as to be pressed.

As described above, since the portable storage device according to the present embodiment is provided with the cover case which is formed by integrated molding and which has supporting sections for supporting the circuit board from the right and left by the elastic force in the state where the circuit board is inserted, it is possible to reduce the number of components of the cover case, and to facilitate the assembling of the portable storage device, as a result of which assembly time and manufacturing costs of the portable storage device can be reduced.

### Fourth Embodiment

In the First and Second Embodiments, there is described a construction in which U-shaped cuts are formed in both right and left side walls of the cover case, and in which supporting sections are formed by making the portions of the side walls in which the U-shaped cuts are formed, folded down inside the cover case. However, in the present embodiment, a construction of the supporting section for supporting the circuit board at a desired position is further described.

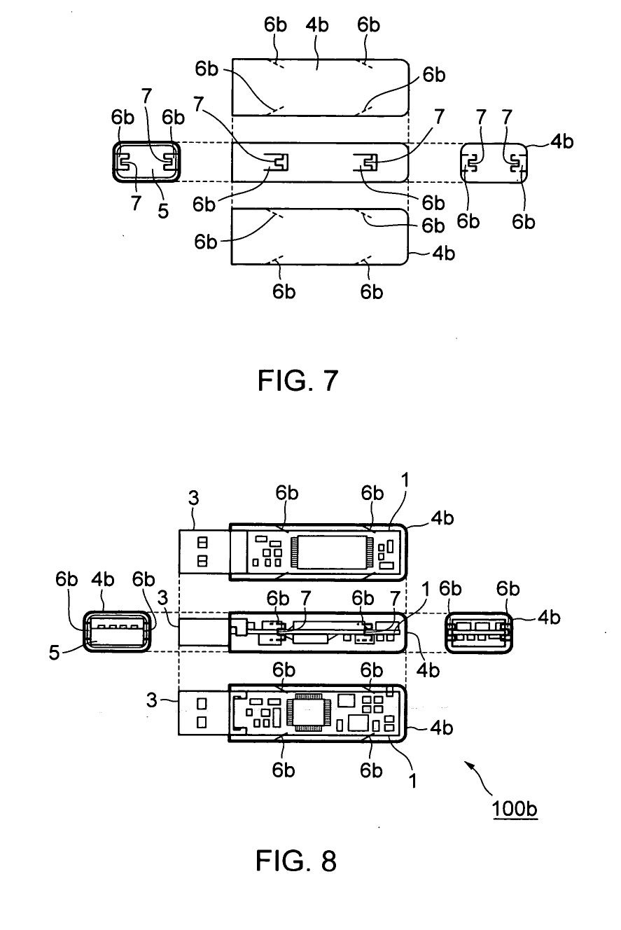

FIG. 7 is a schematic diagram showing a main part construction of a cover case of a portable storage device according to a Fourth Embodiment of the present invention. FIG. 8 is also a schematic diagram showing a main part construction of the portable storage device according to the Fourth Embodiment of the present invention. It is to be noted that in the figure, the same reference numerals as those in the First Embodiment denote the same components as those in the First Embodiment.

As shown in FIG. 7, a cover case 4b has supporting sections 6b formed in both right and left side walls. The supporting sections 6b are formed in such a manner that U-shaped cuts are provided in both right and left side walls of the cover case 4b so as to be open at the rear side, and that the portions of the side walls which are provided with the U-shaped cuts are folded down to project inside the cover case 4b. Furthermore, guide grooves 7 are formed in portions to be in contact with a circuit board 1 at the end of the supporting sections 6b. The guide grooves 7 have, for example, a width of about 0.4 mm or more, so that the right and left ends of the circuit board 1 can be fitted into the guide grooves so as to be guided. In this case, the width of the end of the supporting sections 6b is set to, for example, about 0.6 mm or more. Thus, when the circuit board 1 is inserted into the inside of the cover case 4b, the right and left ends of the circuit board 1 are guided by the guide grooves 7. Furthermore, the circuit board 1 is supported from the right and left by the elastic force of the supporting sections 6b in the state where the circuit board 1 is inserted inside the cover case 4b, while the circuit board 1 is supported by the side wall of the guide grooves 7 so as not to move vertically.

The portable storage device 100b is assembled, similarly to the First Embodiment, in such a manner that the circuit board 1 mounted with electronic components 2 including a semiconductor storage device is inserted to a predetermined position in the opening 5 of the cover case 4b from the rear side of the circuit board 1, so as to make both side surfaces of the circuit board 1 face the supporting sections 6b.

Thereby, as shown in FIG. 8, the circuit board 1 is supported in the cover case 4b in a state where the connector terminal section 3 is exposed, and the portable storage device 100b is completed.

Similarly to the First Embodiment, the portable storage device 100b can be easily assembled without requiring parts such as other bolts, and the circuit board 1 is more reliably supported by the side wall of the guide grooves 7 so as not to be vertically moved.

As described above, in the portable storage device according to the present embodiment, it is possible to shorten assembly time as well as to reduce manufacturing costs. In addition, the circuit board is guided into the supporting sections, and the guide grooves for supporting the circuit board are also provided for the supporting section. As a result, the circuit board can be supported more reliably at a desired position in the cover case.

It is to be noted that in the present embodiment, examples applied to the construction of the supporting sections of the First and Second Embodiments are explained, but the construction of the present embodiment can be similarly applied to the construction of the supporting sections of the Third Embodiment, and the same effects can be obtained by forming the grooves in the respective portions of the supporting sections, which portions are brought into contact with both right and left side surfaces of the circuit board.

### Fifth Embodiment

In each of the above described embodiments, there are described constructions in which the supporting sections are formed in both right and left side walls of the cover case and the circuit board is supported from the right and left. In the present embodiment, however, there is described a construction in which supporting sections for supporting the circuit board from the upper and lower directions are provided for the upper and lower walls of the cover case. It is to be noted that in the present embodiment, a case where the construction is applied to the First Embodiment is explained, but the construction can be similarly applied to the other embodiments.

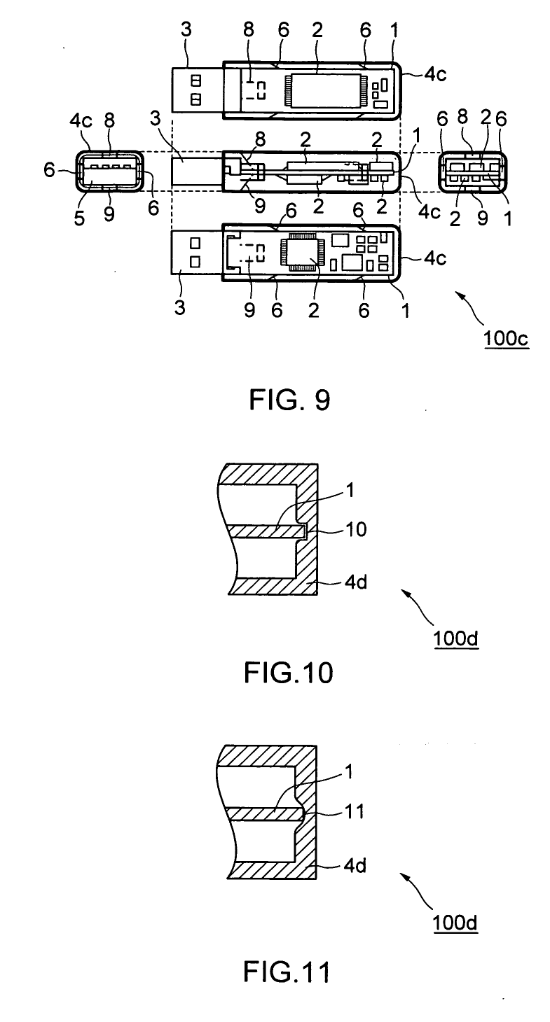

FIG. 9 is a schematic diagram showing a main part construction of a portable storage device according to a Fifth Embodiment of the present invention. It is to be noted that in the figure, the same reference numerals as those in the First Embodiment denote the same components as those in the First Embodiment.

As shown in FIG. 9, a cover case 4c has a supporting section 8 formed by providing a U-shaped cut in the upper wall, and a supporting section 9 similarly formed by providing a U-shaped cut in the lower side wall. These supporting sections 8, 9 are held within the same surfaces as the upper and lower walls of the cover case 4c so as not to be in contact with electronic components 2 on a circuit board 1, until a portable storage device 100c is inserted into the cover case 4c.

In assembling the portable storage device 100c, first, similarly to the First Embodiment, the circuit board 1 mounted with electronic components 2 including a semiconductor storage device is inserted to a predetermined position in the opening 5 of the cover case 4a from the rear side of the circuit board 1, so as to make both side surfaces of the circuit board 1 face the supporting sections 6a.

Next, the upper and lower supporting sections 8, 9 are folded down to project inside the cover case 4c to be brought into contact with the circuit board 1, so that the circuit board 1 is supported from the upper and lower directions by the elastic force of the supporting sections 8, 9.

Thereby, as shown in FIG. 9, the circuit board 1 is supported inside the cover case 4c in the state where the connector terminal section 3 is exposed, and the portable storage device 100c is completed.

The portable storage device 100c can be easily assembled similarly to the First Embodiment, without requiring components such as other bolts.

It is to be noted that in the present embodiment, there is described the construction in which the circuit board 1 is directly supported by the supporting sections 8, 9, but the circuit board 1 may be arranged to be supported via electronic components 2 provided on the circuit board 1. In this case, the electronic components 2 are preferably insulated from the supporting sections 8, 9.

Furthermore, in the present embodiment, there is described the construction in which the circuit board 1 is directly supported by the supporting sections 8, 9 from the upper and lower directions, but the circuit board 1 may be arranged to be supported by only one of the supporting sections 8, 9, that is, one of the upper and lower surfaces of the circuit board 1 may be arranged to be supported. Furthermore, the supporting sections 8, 9 may be provided at plural positions in each of the upper and lower surfaces of the cover case 4c in order to stabilize the support of the circuit board 1.

As described above, in the portable storage device according to the present embodiment, similarly to the First Embodiment, it is possible to shorten assembly time as well as to reduce manufacturing costs. In addition, the supporting sections for supporting the circuit board from the upper and lower directions are provided in the upper and lower walls of the cover case, so that the circuit board can be supported more stably in the cover case.

### Sixth Embodiment

In each of the above described embodiments, there is described the construction in which the supporting sections are formed in both right and left side walls of the cover case and the circuit board is supported from the right and left. However, in the present embodiment, there is described a construction in which a support groove for supporting the circuit board is further provided in the rear side walls of the cover case. It is to be noted that in the present embodiment, a case where the construction is applied to the First Embodiment is explained, but the construction can be similarly applied to the other embodiments.

FIG. 10 is a sectional view showing a main part construction of a portable storage device 100d according to a Sixth Embodiment of the present invention. It is to be noted that in the figure, the same reference numerals as those in the First Embodiment denote the same components as those in the First Embodiment.

As shown in FIG. 10, a support groove 10 into which the rear end of a circuit board 1 is inserted to make the circuit board supported is formed in the rear side wall of a cover case 4d. The support groove 10 has a width of, for example, about 0.4 mm or more so that the circuit board 1 can be fitted into the support groove. The support groove 10 may be integrally formed at the time of molding the cover case 4d, or may be formed by etching and the like after the cover case 4d is molded.

As shown in FIG. 10, the rear end of the circuit board 1 is fitted into the support groove 10, so that it is possible to stably support the circuit board 1 in the vertical direction of the cover case 4d.

It is to be noted that the support groove may have a cross section formed into a tapered shape. Here, FIG. 11 shows a main part construction of a portable storage device having a support groove whose cross section is formed into the tapered shape.

As shown in FIG. 11, even in the case where the circuit board 1 is inserted into the cover case 4d at a predetermined height, the circuit board 1 can be guided at the predetermined height by the tapered inner wall of the support groove 11, by inserting the circuit board 1 to a predetermined depth in the cover case 4d.

As described above, in the portable storage device according to the present embodiment, it is possible to shorten assembly time as well as to reduce manufacturing costs, and it is also possible to more reliably support the circuit board at a predetermined position in the cover case, because the support groove for supporting the circuit board is provided in the rear side walls of the cover case.

### Seventh Embodiment

In the First Embodiment, there is described the construction in which the supporting sections are formed in both right and left side walls of the cover case, so as to support the circuit board from the right and left. In the present embodiment, there is described, in particular, a construction in which a memory chip and a controller chip as electronic components are provided on the surface opposite to the surface on which the metal terminal of the circuit board is formed.

It is to be noted that in the present embodiment, a case where the construction is applied to the First Embodiment is explained, but the construction can be similarly applied to the Third Embodiment.

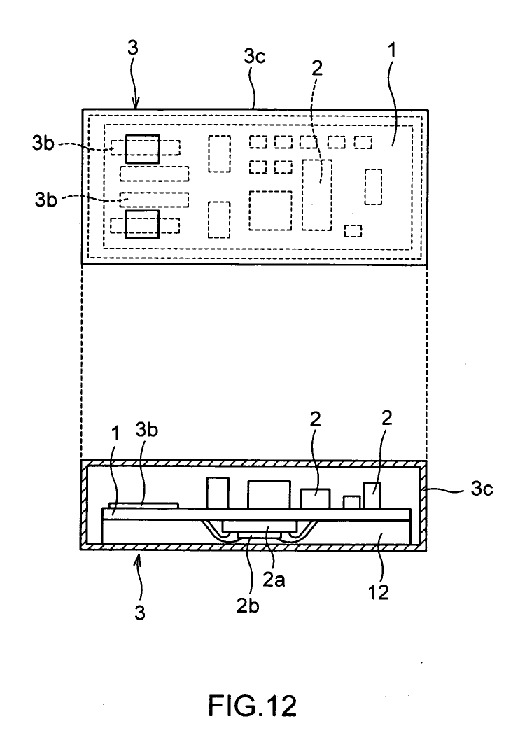

FIG. 12 is a schematic diagram showing a main part construction of a portable storage device according to a Seventh Embodiment of the present invention. It is to be noted that in the figure, the same reference numerals as those in the First Embodiment denote the same components as those in the First Embodiment.

As shown in FIG. 12, metal terminals 3b are directly provided on the front of the upper surface of a circuit board 1. Furthermore, on the lower surface side of the circuit board 1, there are provided a memory chip 2a which is arranged on the circuit board 1 and wire-bonded, and a controller chip 2b which is arranged on the memory chip 2a and wire-bonded. It is to be noted that the controller chip 2b may be arranged directly on the circuit board 1 and wire-bonded.

The memory chips 2a and the controller chip 2b are sealed on the lower surface side of the circuit board 1 by a mold resin 12.

An outer frame section 3c of the connector terminal section 3 is extended backward so as to cover the whole circuit board 1. The circuit board 1 and the outer frame section 3c are fixed to each other for example by bonding the inner surface of the outer frame section 3c and the lower surface of the mold resin 12 to each other. It is to be noted that a metal and the like is selected as the material of the outer frame section 3c.

The outer frame section 3c is inserted for example into the cover case 4 shown in FIG. 2 so that the front of the connector terminal section 3 is exposed. Thereby, the connector terminal section 3 in which the circuit board 1 is fixed, is supported by the supporting sections 6 from the right and left by the elastic force in the cover case 4.

It is to be noted that the circuit board 1 without the outer frame section 3c of the connector terminal section 3 may be directly supported by the supporting sections 6 from the right and left by elastic force in the cover case 4.

As described above, since the portable storage device according to the present embodiment is provided with the cover case which is formed by integrated molding, and which has supporting sections for supporting the circuit board from the right and left by the elastic force, in the state where the connector terminal section with the circuit board fixed therein is inserted, it is possible to reduce the number of components of the cover case, and to facilitate the assembling of the portable storage device, as a result of which assembly time and manufacturing costs of the portable storage device can be reduced.

It is to be noted that in each of the above described embodiments, the case where the electronic components 2 including a semiconductor storage device are provided on the upper surface side and the lower surface side of the circuit board 1 is explained, but the present invention can be applied to the case where the electronic components are provided on one of the upper surface side and the lower surface side.

Furthermore, in each of the above described embodiments, the case cover is explained as being formed by integrated molding. However, according to the present invention, even in the case where the cover case is formed by plural components, at least, incorporation of the circuit board into the cover case can be facilitated.

Furthermore, in each of the above described embodiments, there is described an example in which two supporting sections are formed in each of both right and left side walls of the cover case in order to stably support the circuit board, but one supporting section may be formed in each of both right and left side walls of the cover case, or three or more supporting sections may also be formed.

What is claimed is:

1. A portable storage device comprising:
a rectangular cover case having an opening formed on a front side surface;
a circuit board which is supported in the cover case in a state of being inserted in the cover case from the opening, and which is provided with a connector terminal section in a front part; and
a semiconductor storage device which is mounted on at least one of an upper surface side and a lower surface side of the circuit board and is connected with the connector terminal section, and which stores predetermined data,
wherein the cover case has supporting sections which are formed in both right and left side walls of the cover case and which support the circuit board from right and left by elastic force in a state where the circuit board is inserted in the cover case.

2. The portable storage device according to claim 1, wherein the supporting sections are formed in a manner that portions of the both right and left side walls of the cover case, in which portion a cut is formed, are shaped to project to the inner face side of the cover case.

3. The portable storage device according to claim 1, wherein the supporting sections have guide grooves for guiding and supporting both right and left side walls of the circuit board when the circuit board is inserted into the cover case.

4. The portable storage device according to claim 1, wherein the cover case has a supporting section which is formed in at least one of an upper wall and a lower wall of the cover case, and which supports the circuit board in a vertical direction.

5. The portable storage device according to claim 1, wherein a support groove for supporting a rear end of the circuit board is formed in a rear side wall of the cover case.

6. The portable storage device according to claim 1, wherein the semiconductor storage device includes a memory chip which is arranged on the circuit board and wire-bonded, and a controller chip which is arranged on the memory chip or on the circuit board and wire-bonded, and
wherein the memory chip and the controller chip are sealed on the circuit board by a mold resin.

7. The portable storage device according to claim 1, wherein the cover case is made of plastic or metal.

8. The portable storage device according to claim 7, wherein the cover case is formed by integrated molding.

9. The portable storage device according to claim 5, wherein the support groove has a cross section formed into a tapered shape.

10. The portable storage device according to claim 2, wherein each cut in the both right and left side walls of the cover case is formed by providing a U-shaped cut to be open at rear side, and
wherein each of the supporting sections is formed by shaping in a manner that the portion of the side wall in which the U-shaped cut is formed is folded down to project inside the cover case.

11. The portable storage device according to claim 10, wherein the cover case is made of plastic or metal.

12. The portable storage device according to claim 11, wherein the cover case is formed by integrated molding.
